(19) United States
(12) Patent Application Publication
(10) Pub. No.: US 2025/0287696 A1
(43) Pub. Date: Sep. 11, 2025

(54) RF Amplifier with Integrated Harmonic Termination Circuit

(71) Applicant: MACOM Technology Solutions Holdings, Inc., Lowell, MA (US)

(72) Inventor: Jeremy Fisher, Raleigh, NC (US)

(21) Appl. No.: 18/598,739

(22) Filed: Mar. 7, 2024

(51) Int. Cl. H01L 27/06; H01L 21/8234; H01L 23/00; H01L 23/48; H03F 3/19

(52) U.S. Cl. CPC H10D 88/00; H01L 23/481; H01L 24/48; H01L 24/49; H10D 84/0126; H10D 84/038; H01L 2224/48091; H01L 2224/4813; H01L 2224/48137; H01L 2224/49175; H01L 2924/30107; H03F 3/19; H03F 2200/451

(57) ABSTRACT

A harmonic termination circuit is integrated into an RF amplifier semiconductor structure. A MIMcap is formed on a grounded source finger of an RF transistor amplifier, and one or more bond wires connect the MIMcap to a gate or drain bond pad of the transistor. The bond wire has an inherent inductance, and together with the MIMcap forms a series LC resonant circuit connected in shunt configuration from the gate or drain bond pad to ground. The LC circuit is tuned to shunt the desired harmonic component to ground, such as by adjusting the length of the bond wire (e.g., by altering its height). Such adjustment can be made after fabrication of the integrated circuit die is complete, and can be changed without requiring re-fabrication. The harmonic termination circuit resides entirely within the amplifier area, and does not increase the size of the die.

### BACKGROUND

Electrical circuits requiring high power handling capability while operating at high frequencies, such as R-band (0.5-1 GHz), L-band (1-2 GHz), S-band (2-4 GHz), C-Band (4-8 GHz), X-band (8-12 GHz), Ku-band (12-18 GHz), K-band (18-27 GHz), Ka-band (27-40 GHz) and V-band (40-75 GHz) have become more prevalent. In particular, there is now a high demand for radio frequency (“RF”) transistor amplifiers that are used to amplify RF signals at frequencies of, for example, 500 MHz and higher (including microwave frequencies). These RF transistor amplifiers may need to exhibit high reliability, good linearity and handle high output power levels.

RF amplifiers are widely used in wireless communications systems and other applications. RF amplifiers are typically formed as semiconductor integrated circuit chips. Most RF amplifiers are implemented in silicon or using wide bandgap semiconductor materials, such as silicon carbide (“SiC”) and Group III nitride materials. As used herein, the term “Group III nitride” refers to those semiconducting compounds formed between nitrogen and the elements in Group III of the periodic table, usually aluminum (Al), gallium (Ga), and/or indium (In). The term also refers to ternary and quaternary compounds, such as GaN-based compounds AlGaN and AlInGaN. These compounds have empirical formulas in which one mole of nitrogen is combined with a total of one mole of the Group III elements.

Silicon-based RF amplifiers are typically implemented using laterally diffused metal oxide semiconductor (“LDMOS”) transistors. Silicon LDMOS RF amplifiers can exhibit high levels of linearity and may be relatively inexpensive to fabricate. Group III nitride-based RF amplifiers are typically implemented using High Electron Mobility Transistors (“HEMT”) and are primarily used in applications requiring high power and/or high frequency operation where LDMOS transistor amplifiers may have inherent performance limitations.

RF amplifiers may include one or more amplification stages, with each stage typically implemented as a transistor amplifier. In order to increase the output power and current handling capabilities, RF amplifiers are typically implemented in a “unit cell” configuration in which a large number of individual “unit cell” transistors are arranged electrically in parallel. The RF amplifier may be implemented as a single integrated circuit chip or “die,” or may include a plurality of dies. When multiple RF amplifier dies are used, they may be connected in series and/or in parallel.

RF amplifiers are typically designed to amplify RF signals at a fundamental frequency or range of frequencies. Ideally, for a transistor biased to class A operation, an output signal amplitude would be a constant multiple of the input amplitude:

Vₒᵤₜ=AVᵢₙ

Due to inherent nonlinearities in transistor operation, the signal output by any real-world transistor amplifier includes not only the amplified RF signal at its fundamental frequency, but additionally signal components at multiples, or harmonics, of the fundamental frequency. A general equation for the actual output of a transistor biased to class A operation is:

$${V}_{out} = {AV}_{in} + B {V}_{in}^{2} + C {V}_{in}^{3} + …$$

The second term of this equation is known as the second-order harmonic or distortion (and the third term is the third-order harmonic, etc.). Harmonic signal components cause constructive and destructive interference with the fundamental frequency signal, resulting in non-linearities in the amplifier's output which must be compensated (e.g., by pre-distortion). Harmonics also reduce the efficiency of RF amplifier operation.

Accordingly, harmonic termination circuits are well known in the art. Harmonic termination circuits are typically implemented as resonant circuits, which form a low-impedance path to RF signal ground at a targeted frequency or range of frequencies (e.g., 2^{nd} or 3^{rd} order harmonic frequencies). For example, U.S. Pat. No. 11,114,988 discloses a harmonic termination circuit integrated with the impedance inverter of a Doherty amplifier. The resonant circuits may be formed using transmission lines or discrete reactive components, such as inductors and capacitors. These components may be external (“off-chip”), which increases component count and limits RF amplifier deployment options to situations that can support off-chip components, such as a Printed Circuit Board (PBC).

Alternatively, the components can be formed on-chip. Inductors are formed in integrated circuits by routing metal traces in a spiral or serpentine pattern, close enough that the magnetic fields generated by current in the traces overlap. Capacitors can be formed on integrated circuits by depositing a metal layer as the bottom plate, depositing an insulating layer over the bottom plate, and depositing another metal layer over the insulating layer (known as a Metal-Insulator-Metal capacitor, or MIMcap). Forming these components increases the size, and therefore the cost, of the integrated circuit die. Additionally, the size and configuration of the reactive components must be precisely correct. That is, to alter the resonant frequency of a harmonic termination circuit, the inductor and/or capacitor structure must be redesigned, and the die re-fabricated, further increasing the cost.

The Background section of this document is provided to place embodiments of the present invention in technological and operational context, to assist those of skill in the art in understanding their scope and utility. Unless explicitly identified as such, no statement herein is admitted to be prior art merely by its inclusion in the Background section

### BRIEF SUMMARY

The following presents a simplified summary of the disclosure in order to provide a basic understanding to those of skill in the art. This summary is not an extensive overview of the disclosure and is not intended to identify key/critical elements of embodiments of the invention or to delineate the scope of the invention. The sole purpose of this summary is to present some concepts disclosed herein in a simplified form as a prelude to the more detailed description that is presented later.

According to aspects of the present disclosure described and claimed herein, a harmonic termination circuit comprises a MIMcap integrated into a source finger of an RF transistor amplifier, and one or more bond wires connecting the MIMcap to a gate or drain bond pad of the transistor. The source terminal is electrically connected to RF signal ground, such as through a plated via to a metal layer on the back side of the die substrate. The bond wire has an inherent inductance, and together with the MIMcap forms a series LC resonant circuit connected in shunt configuration from the gate or drain bond pad to ground. The LC circuit is tuned to shunt the desired harmonic component to ground, such as by adjusting the length of the bond wire (e.g., by altering its height). Note that such adjustment can be made after fabrication of the integrated circuit die is complete, and can be changed without requiring re-fabrication. Because the MIMcap is formed on the source finger, and connected to a gate or drain bond pad, the harmonic termination circuit resides entirely within the amplifier area, and does not increase the size of the die.

One aspect relates to a semiconductor transistor configured to amplify a Radio Frequency (RF) signal at a fundamental frequency. The transistor includes a substrate having upper and lower surfaces, and a unit cell semiconductor transistor structure formed on the upper surface of the substrate. The transistor also includes source and drain fingers formed on, and electrically connected to, the semiconductor transistor structure. The transistor further includes gate fingers formed over the semiconductor transistor structure in active areas between the source and drain fingers. The transistor additionally includes gate and drain bond pads connected to respective gate and drain fingers. The source fingers are electrically connected to RF signal ground. A series resonant circuit is connected between one of the gate and drain bond pads and a source finger. The series resonant circuit comprises a Metal-Insulator-Metal (MIM) capacitor formed on the source finger, and an inductance implemented as a bond wire connected between the gate or drain bond pad and the MIM capacitor.

Another aspect relates to a method of manufacturing a semiconductor transistor configured to amplify a Radio Frequency (RF) signal at a fundamental frequency. A substrate having upper and lower surfaces is provided. A unit cell semiconductor transistor structure is formed on the upper surface of the substrate. Source and drain fingers are formed on, and electrically connected to, the semiconductor transistor structure. Gate fingers are formed over the semiconductor transistor structure in active areas between the source and drain fingers. Gate and drain bond pads, connected to respective gate and drain fingers, are formed. The source fingers are electrically connected to RF signal ground. A series resonant circuit, connected between one of the gate and drain bond pads and a source finger, is formed by forming a Metal-Insulator-Metal (MIM) capacitor on the source finger, and connecting a bond wire between the gate or drain bond pad and the MIM capacitor.

### BRIEF DESCRIPTION OF THE DRAWINGS

FIG. 1 is a top section view of an RF transistor amplifier device.

FIG. 2 is a side section view of the RF transistor amplifier device.

FIG. 3 is a schematic electrical diagram of an amplifier with a harmonic termination circuit.

FIG. 4A is top sectional view of harmonic termination circuits connected to a gate pad.

FIG. 4B is top sectional view of some harmonic termination circuits connected to a gate pad and others to a drain pad.

FIG. 4C is top sectional view of harmonic termination circuits connected to a drain pad, with an alternate location of MIMcaps on the source fingers.

FIG. 4D is top sectional view of harmonic termination circuits connecting each source finger to both a gate pad and a drain pad.

FIG. 5 is a flow diagram of a method of manufacturing an RF amplifier.

FIG. 6 is a side section view of the RF transistor amplifier device.

FIG. 7 is a side section view of the RF transistor amplifier device in a first packaging option.

FIG. 8 is a side section view of the RF transistor amplifier device in a second packaging option.

FIG. 9 is a side section view of the RF transistor amplifier device in a third packaging option.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Reference now will be made in detail to aspects of the present disclosure, one or more examples of which are illustrated in the drawings. Each example is provided by way of explanation of the aspect, not limitation of the present disclosure. In fact, it will be apparent to those skilled in the art that various modifications and variations can be made to the aspects without departing from the scope or spirit of the present disclosure. For instance, features illustrated or described as part of one aspect can be used with another aspect to yield a still further aspect. Thus, it is intended that aspects of the present disclosure cover such modifications and variations.

Transistor devices, such as High Electron Mobility Transistors (HEMT), may be used in power electronics applications. HEMTs fabricated in Group III nitride-based material systems may have the potential to generate large amounts of radio frequency (RF) power because of the combination of material characteristics that includes high breakdown fields, wide bandgaps, large conduction band offset, and/or high saturated electron drift velocity. As such, Group III nitride based HEMTs may be promising candidates for high frequency and/or high-power RF applications, as well as for low frequency high power switching applications, both as discrete transistors or as coupled with other circuit elements, such as in Monolithic Microwave Integrated Circuit (MMIC) devices.

Transistor devices such as HEMT devices may be classified into depletion mode and enhancement mode types, corresponding to whether the transistor is in an ON-state or an OFF-state at a gate-source voltage of zero. In enhancement mode devices, the devices are OFF at zero gate-source voltage, whereas in depletion mode devices, the device is ON at zero gate-source voltage. Often, high performance Group III nitride-based HEMT devices may be implemented as depletion mode (normally-on) devices, in that they are conductive at a gate-source bias of zero due to the polarization-induced charge at the interface of the barrier and channel layers of the device.

When an HEMT device is in an ON-state, a 2-Dimensional Electron Gas (2DEG) is formed at the heterojunction of two semiconductor materials with different bandgap energies, where the smaller bandgap material has a higher electron affinity. The 2DEG is an accumulation layer in the smaller bandgap material and can include a very high sheet electron concentration. Additionally, electrons that originate in the wider-bandgap semiconductor material transfer to the 2DEG layer, allowing high electron mobility due to reduced ionized impurity scattering. This combination of high carrier concentration and high carrier mobility may give the HEMT device a very large transconductance (which may refer to the relationship between output current and input voltage) and may provide a strong performance advantage over MOSFETs for high-frequency applications.

Aspects of the present disclosure are described herein with reference to plan view and cross-section illustrations that are schematic illustrations of idealized embodiments (and intermediate structures) of aspects of the disclosure. The thickness of layers and regions in the drawings may be exaggerated for clarity. Additionally, variations from the shapes of the illustrations as a result, for example, of manufacturing techniques and/or tolerances, are to be expected. Thus, aspects of the disclosure should not be construed as limited to the particular shapes of regions illustrated herein but are to include deviations in shapes that result, for example, from manufacturing. Similarly, it will be understood that variations in the dimensions are to be expected based on standard deviations in manufacturing procedures. As used herein, “approximately” or “about” includes values within 10% of the nominal value.

Like numbers refer to like elements throughout. Thus, the same or similar numbers may be described with reference to other drawings even if they are neither mentioned nor described in the corresponding drawing. Also, elements that are not denoted by reference numbers may be described with reference to other drawings.

Some aspects of the disclosure are described with reference to semiconductor layers and/or regions which are characterized as having a conductivity type such as n type or p type, which refers to the majority carrier concentration in the layer and/or region. Thus, N type material has a majority equilibrium concentration of negatively charged electrons, while P type material has a majority equilibrium concentration of positively charged holes.

Aspects of the present disclosure are discussed with reference to an HEMT transistor device for purposes of illustration and discussion. Those of ordinary skill in the art, using the disclosures provided herein, will appreciate that certain aspects of the present disclosure may be applicable to other transistor devices without deviating from the scope of the present disclosure. For instance, aspects of the present disclosure may be implemented in any transistor having a field plate or other transistors devices with metal structures, such as silicon carbide-based MOSFETs.

In the drawings and specification, there have been disclosed typical embodiments and, although specific terms are employed, they are used in a generic and descriptive sense only and not for purposes of limitation of the scope set forth in the following claims.

With reference now to the Figures, example aspects of the present disclosure will now be set forth. These aspects are described herein with reference to a Gallium Nitride (GaN) High Electron Mobility Transistor (HEMT), but are not limited to such implementation. For example, aspects of the present disclosure may advantageously be implemented using LDMOS or Gallium Arsenide (GaAs). To provide a full and complete disclosure enabling one of skill in the art to make and use the present disclosure, a description of a GaN HEMT is first presented. The discussion will then shift to the metal layers overlying a semiconductor transistor structure (again, using GaN HEMT as merely an example), which provide conductivity for interconnection with other circuitry.

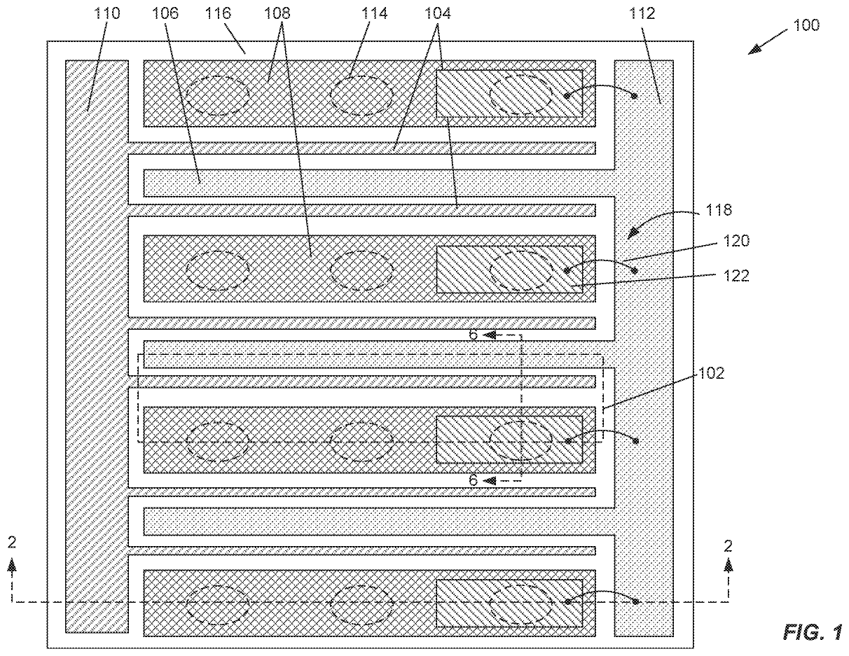

FIG. 1 depicts a top section view of an RF power amplifier, which for the purposes of explanation herein comprises a Group III nitride-based HEMT RF amplifier 100. The HEMT device 100 has a plurality of unit cell transistors 102 that each include a gate finger 104, a drain finger 106, and a source finger 108. The gate fingers 104 are electrically connected to a common gate pad 110, and the drain fingers 106 are electrically connected to a common drain pad 112. The source fingers 108 are electrically connected to a device source terminal via a plurality of conductive source vias 114 that extend through the semiconductor layer structure 116. The conductive source vias 114 may comprise metal-plated vias that extend completely through the semiconductor substrate 116. The conductive source vias 114 may electrically connect to a metal layer covering the back side of the semiconductor substrate 116, which may be connected to RF signal ground. At least the gate pad 110, drain pad 112, and source fingers 108 are the highest, or uppermost, layers of the semiconductor device 100.

According to aspects of the present disclosure, a harmonic termination circuit 118 is formed at the output of at least one, and up to all, of the unit cell transistors 102. The harmonic termination circuit 118 comprises a MIMcap 122 formed on the source finger 108 and a wire bond 120 connecting the MIMcap 122 to, in the case depicted, the drain pad 112.

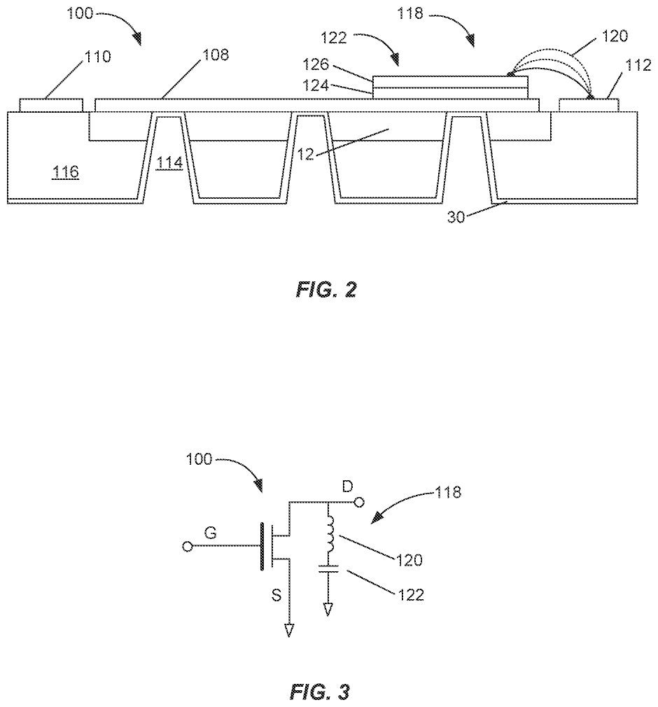

FIG. 2 depicts a side section view of the RF amplifier 100, as indicated by the section line in FIG. 1. FIG. 2 is intended to represent structures for identification and description and is not intended to represent the structures to physical scale. FIG. 2 shows the RF amplifier 100 comprising a substrate 116, with a semiconductor transistor structure 12 formed over the substrate 116 in an active area, as explained in greater detail herein. The semiconductor transistor structure 12 may comprise a Group III-nitride HEMT structure.

A back side metal plate 30 is formed on the opposite side of the substrate 116 from the semiconductor transistor structure 12. The back side metal plate 30 may electrically connect to the plated vias 114, which extend through the substrate 116. The back side metal plate 30 connects to a device source terminal, which may be electrically connected to RF signal ground. The gate pad 110 and drain pad 112 are formed on the substrate 116 (or on intervening layers). The source finger 108 is formed on the substrate 116, over the active area of the semiconductor transistor structure 12. The source finger 108 covers, and is electrically connected to, one or more plated vias 114.

As described above, the output harmonic termination circuit 118 comprises a MIMcap 122 formed on the source finger 108, connected to the drain pad 112 by one or more bond wires 120. The MIMcap 122 is formed by depositing a dielectric layer 124 directly on at least a portion of the source finger 108, and depositing a metal layer 126 directly on the dielectric layer 124. The source finger 108 forms the bottom plate of the MIMcap 122, with the metal layer 126 forming the top plate. The source finger 108, and hence the MIMcap 122, is connected to RF signal ground by the plated via(s) 114. The MIMcap 122 is thus a capacitor connected to ground. As known in the art, the capacitance of the MIMcap 122 may be adjusted by the size of the metal layer 126, the thickness of the dielectric layer 124, the dielectric constant, and the like.

The bond wire(s) 120 connecting the MIMcap 122 to the drain pad 112 have an inherent parasitic inductance. The inductance of the bond wire(s) 120 may be adjusted by adjusting the length, which may be adjusted by varying the points along the drain pad 112 and MIMcap 122 at which the wire is bonded. The inductance may further be adjusted by altering the height of the “loop” the bond wire 120 forms, as indicated by dotted lines in FIG. 2, which also varies its length.

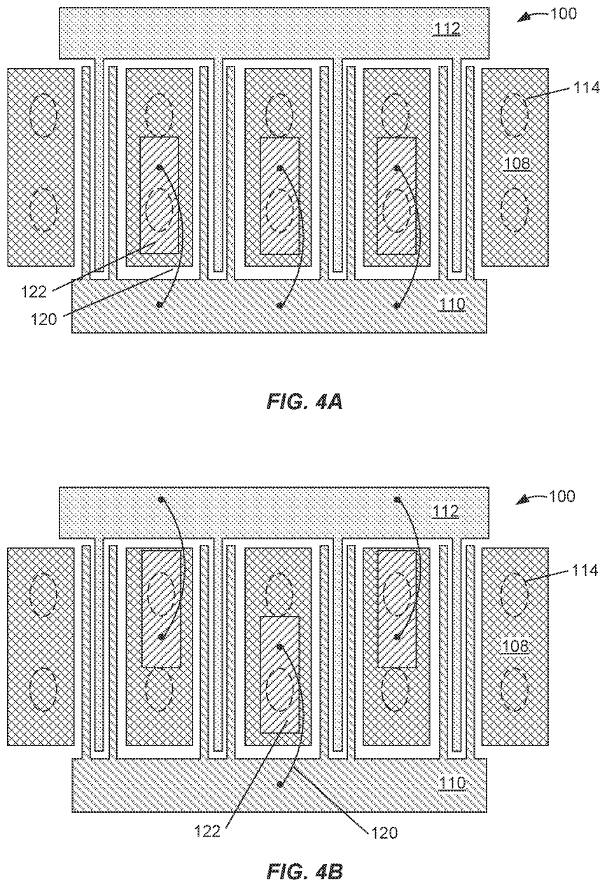

FIG. 3 is an electrical schematic representation of the RF amplifier 100 of FIGS. 1 and 2. The amplifier 100 comprises a transistor having gate, drain, and source terminals, wherein the source terminal is electrically connected to RF signal ground. An output harmonic termination circuit 118 is coupled between the drain terminal and ground. The harmonic termination circuit 118 comprises a series LC resonant circuit comprising an inductance 120 and capacitance 122. The series LC circuit is configured to present a high impedance at a fundamental operating frequency of the amplifier 100, and a low impedance at a selected harmonic of the fundamental frequency. Hence, the harmonic termination circuit 118 has no effect on signals at the fundamental frequency, but shunts signals at the harmonic frequency to ground.

Those of skill in the art will readily recognize that a harmonic termination circuit 118 may alternatively or additionally be configured as an input harmonic termination circuit, wherein the bond wire(s) 120 connects the gate pad 110 to the MIMcap 122. Both input and output harmonic termination circuits 118 may be provided, in any given implementation. Input and output harmonic termination circuits 118 may be combined in any combination.

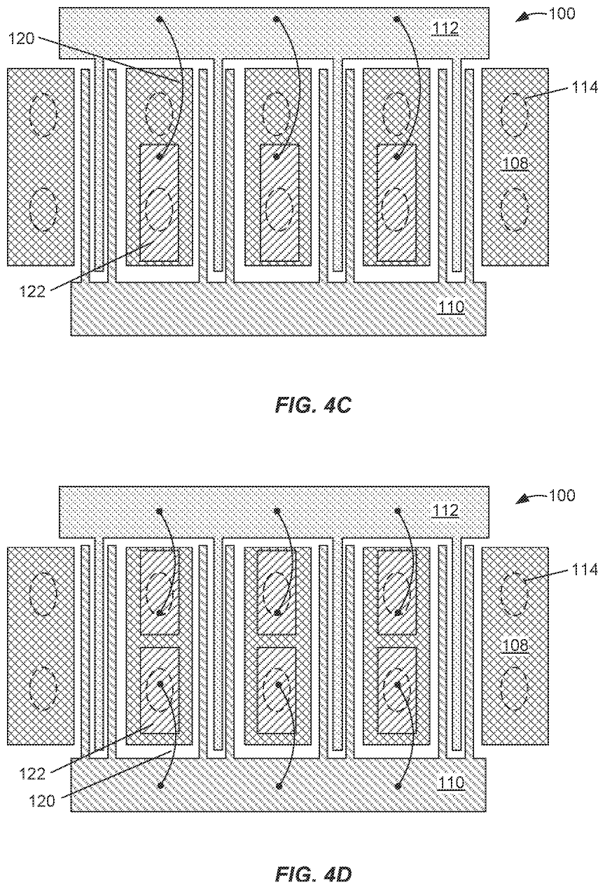

As exemplary and non-limiting examples, FIGS. 4A-D depict some of these variations. FIG. 4A depicts input harmonic termination circuits 118, wherein MIMcaps 122 formed on the source fingers 108 are connected by bond wires 120 to the gate bond pad 110. Although three input harmonic termination circuits 118 are depicted, any number may be provided, as required or desired. Where more than one input harmonic termination circuit 118 is provided, they may be tuned to different harmonics of the fundamental frequency (i.e., the 2^{nd} harmonic, 3^{rd} harmonic, etc.).

FIG. 4B shows both input and output harmonic termination circuits 118, wherein one MIMcap 122 is formed on the source fingers 108, and each is connected by bond wires 120 to either the gate bond pad 110 and source bond pad 112. The harmonic termination circuits 118 may be tuned to the same, or different, harmonics of the fundamental frequency.

FIG. 4C shows output harmonic termination circuits 118, wherein MIMcaps 122 formed on the source fingers 108 are connected by bond wires 120 to the drain bond pad 110. Note that in this example, the MIMcaps 122 are formed on a more distant region of the source fingers 108—that is, spaced apart from the drain bond pad 112. This may allow for a longer bond wire 120, increasing the inductance in the series resonant circuit that forms each harmonic termination circuit 118.

Finally, FIG. 4D shows both input and output harmonic termination circuits 118 connected to each source finger 108. In this case, two separate and electrically isolated (other than both being grounded) MIMcaps 122 are formed on each source finger 108. One such MIMcap 122 is connected by a bond wire 120 to the gate bond pad 110, and the other MIMcap 122 is connected by a bond wire 120 to the source bond pad 112.

Those of skill in the art will readily recognize that the configurations shown in FIGS. 4A-D are representative only, and are not limiting. In general, a broad range of configurations of RF transistors 100 incorporating harmonic termination circuits 118 are possible within the scope of the present disclosure.

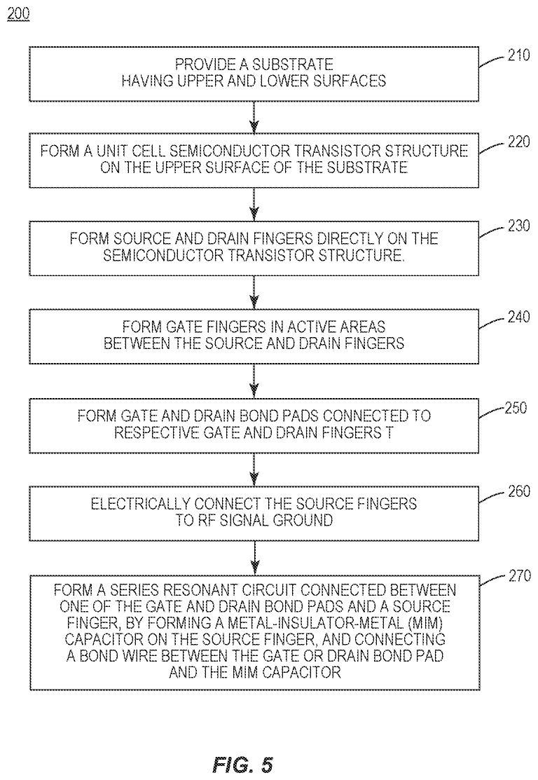

FIG. 5 depicts the steps in a method 200 of manufacturing a semiconductor transistor 100 configured to amplify a Radio Frequency (RF) signal at a fundamental frequency. A substrate 116 having upper and lower surfaces is provided (block 210). A unit cell semiconductor transistor structure 12 is formed on the upper surface of the substrate 116 (block 220). Source and drain fingers 106, 108 are formed directly on, and electrically connected to, the semiconductor transistor structure 12 (block 230). Gate fingers 104 are formed over the semiconductor transistor structure 12 in active areas between the source and drain fingers 106, 108 (block 240). Gate and drain bond pads 110, 112, connected to respective gate and drain fingers 104, 106, are formed (block 250). The source fingers 108 are electrically connected to RF signal ground (block 260). A series resonant circuit 118, connected between one of the gate and drain bond pads 110, 112 and a source finger 108, is formed by forming a Metal-Insulator-Metal (MIM) capacitor 122 on the source finger 108, and connecting a bond wire 120 between the gate or drain bond pad 110, 112 and the MIM capacitor 122 (block 270).

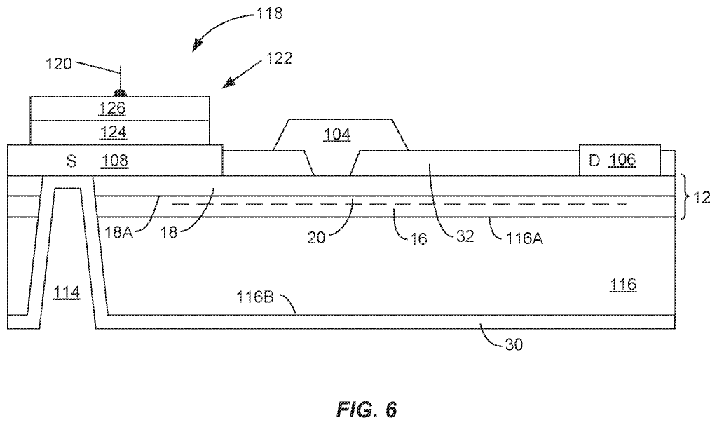

FIG. 6 depicts a side section view of a unit cell transistor 102 of the HEMT device 100, as indicated by the section line in FIG. 1. FIG. 6 is intended to represent structures for identification and description and is not intended to represent the structures to physical scale. The unit cell transistor 102 of the HEMT device 100 includes a semiconductor transistor structure 12. The semiconductor transistor structure 12, in this representative example, is a Group III-nitride HEMT structure.

As used herein, the term “Group III nitride” refers to those semiconducting compounds formed between nitrogen (N) and the elements in Group III of the periodic table, usually aluminum (Al), gallium (Ga), and/or indium (In). The term also refers to ternary and quaternary (or higher) compounds such as, for example, AlGaN and AlInGaN. As is well understood by those in this art, the Group III elements may combine with nitrogen to form binary (e.g., GaN), ternary (e.g., AlGaN, AlInN), and quaternary (e.g., AlInGaN) compounds. These compounds all have empirical formulas in which one mole of nitrogen is combined with a total of one mole of the Group III elements.

The semiconductor transistor structure 12 is formed on a substrate 116. The substrate 116 may be a semiconductor material. For instance, the substrate 116 may be a silicon substrate, a silicon carbide (SiC) substrate, a sapphire substrate, or other suitable substrate. In some aspects, the substrate 116 may be a semi-insulating SiC substrate that may be, for example, the 4H polytype of silicon carbide. Other SiC candidate polytypes may include the 3C, 6H, and 15R polytypes. The substrate may be a High Purity Semi-Insulating (HPSI) substrate, available from Wolfspeed, Inc. The term “semi-insulating” is used descriptively herein, rather than in an absolute sense.

In some aspects of the present disclosure, the SiC bulk crystal of the substrate 116 may have a resistivity equal to or higher than about 1×10⁵ ohm-cm at room temperature. Example SiC substrates that may be used in some embodiments are manufactured by, for example, Wolfspeed, Inc., and methods for producing such substrates are described, for example, in U.S. Pat. No. Re. 34,861, U.S. Pat. Nos. 4,946,547; 5,200,022; and 6,218,680; the disclosures of which are incorporated by reference herein in their entireties. Although SiC may be used as a substrate material, aspects of the present disclosure may utilize any suitable substrate, such as sapphire (Al2O3), aluminum nitride (AlN), aluminum gallium nitride (AlGaN), gallium nitride (GaN), silicon (Si), GaAs, LGO, zinc oxide (ZnO), LAO, indium phosphide (InP), and the like. The substrate 116 may be a SiC wafer, and the HEMT device 100 may be formed, at least in part, via wafer-level processing, and the wafer may then be diced to provide a plurality of individual HEMT devices 100 that may include one or more transistor cells 102.

In some aspects of the present disclosure, the substrate 116 of the HEMT device 100 may be a thinned substrate 116. In some embodiments, the thickness of the substrate 116 may be about 100 μm or less, such as about 75 μm or less, such as about 50 μm or less.

The semiconductor transistor structure 12 includes a channel layer 16 on an upper surface 116A of the substrate 116 (or on optional layers, not shown in FIG. 1, deposited over the substrate, such as an optional buffer or nucleation layer). The semiconductor transistor structure 12 also includes a barrier layer 18 on an upper surface of the channel layer 16. In some aspects, the channel layer 16 and the barrier layer 18 may each be formed by epitaxial growth. Techniques for epitaxial growth of Group III nitrides have been described in, for example, U.S. Pat. Nos. 5,210,051, 5,393,993, and 5,523,589, the disclosures of which are incorporated by reference herein in their enteritis. The channel layer 16 has a bandgap that is less than the bandgap of the barrier layer 18. The channel layer 16 has a larger electron affinity than the barrier layer 18. The channel layer 16 and the barrier layer 18 include Group III nitride-based materials.

In some aspects, the channel layer 16 is a Group III nitride, such as AlₓGa₁₋ₓN, where x is about 0.1 or less, provided that the energy of the conduction band edge of the channel layer 16 is less than the energy of the conduction band edge of the barrier layer 18 at the interface between the channel layer 16 and barrier layer 18 (also known as a heterojunction). In some embodiments, the aluminum mole fraction x is approximately 0 (e.g., less than 5%, such as 0%), indicating that the channel layer 16 is GaN. The channel layer 16 may or may not include other Group III-nitrides such as InGaN, AlInGaN or the like. The channel layer 16 may be undoped (“unintentionally doped”). In some aspects, the channel layer 16 may be doped, for instance with iron (Fe). The channel layer 16 may be a multi-layer structure, such as a superlattice or combinations of GaN, AlGaN, or the like. The channel layer 16 may be under compressive strain in some aspects. In some aspects, the channel layer 16 can include an implanted region extending into the channel layer 16. The implanted region may have implanted dopants to provide, for instance, N-type doping of the semiconductor structure in the implanted region, such as in the region on which source and drain terminals are formed.

The barrier layer 18 includes a Group III nitride-based layer having a surface 18A positioned on a surface 16A of the channel layer 16. The barrier layer 18 is a Group III-nitride, such as Al_{y}Ga_{1-y}N, where y is the aluminum mole fraction in the barrier layer 18. In some embodiments, the aluminum mole fraction y is such that y is in a range of about 0.25 to about 0.40 (e.g., the aluminum mole fraction is in a range of about 25% to about 40%), indicating that the barrier layer is an AlGaN layer. For instance, in some embodiments, the aluminum mole fraction y is such that y is in a range from about 0.25 to about 0.35, such as about 0.25 to 0.30, such as about 0.30 (e.g., the aluminum mole fraction is in a range of about 25% to about 35%, such as about 25% to about 30%, such as about 30%). Additionally or alternatively, in some aspects, the aluminum mole fraction y is such that y is in a range of about 0.30 to about 0.40, such as about 0.35 to about 0.40, such as about 0.35 (e.g., the aluminum mole fraction is in a range of 30% to 40%, such as in a range of about 35% to about 40%, such as about 35%). For instance, in some implementations, the barrier layer 18 can include a higher aluminum mole fraction to achieve low contact resistance for high frequency applications.

The energy of the conduction band edge of the barrier layer 18 is greater than the energy of the conduction band edge of the channel layer 16 at the interface between the channel layer 16 and barrier layer 18. The barrier layer 18 may include other Group III elements (e.g., In) without deviating from the scope of the present disclosure. The barrier layer 18, in some examples, may be a multilayer structure. The multilayer structure may include multiple Group III nitride-based layers with differing aluminum mole fractions.

The barrier layer 18 may have a thickness less than about 130 Angstroms, such as in a range of about 10 Angstroms to about 130 Angstroms. For instance, in some aspects, the barrier layer can have a thickness in a range of about 70 Angstroms to about 100 Angstroms, such as about 80 Angstroms to about 90 Angstroms. For instance, in some implementations, the barrier layer 18 can have a reduced thickness to achieve low contact resistance for high frequency applications. The channel layer 16 and/or the barrier layer 18 may be deposited, for example, by metal-organic chemical vapor deposition (MOCVD), molecular beam epitaxy (MBE), or hydride vapor phase epitaxy (HVPE).

A 2DEG 20 is induced in the channel layer 16 at an interface between the channel layer 16 and the barrier layer 18. The 2DEG 20 is highly conductive and allows conduction between the source and drain regions of the HEMT device 100.

While the HEMT unit cell transistor 102 of FIG. 4 is shown with a substrate 116, channel layer 16 and barrier layer 18 for purposes of illustration, the HEMT device 100 may include additional layers/structures/elements. For instance, the HEMT device 100 may include a buffer layer(s)/nucleation layer(s)/transition layer(s) (not shown) between substrate 116 and the channel layer 16. For example, an AlN buffer layer may be on the upper surface 116A of the substrate 116 to provide an appropriate crystal structure transition between a SiC substrate 116 and the channel layer 16. The optional buffer/nucleation/transition layers may be deposited by MOCVD, MBE, and/or HYPE.

The HEMT device 100 may include a cap layer (not shown) on the barrier layer 18. HEMT structures including substrates, channel layers, barrier layers, and other layers are discussed by way of example in U.S. Pat. Nos. 5,192,987; 5,296,395; 6,316,793; 6,548,333; 7,544,963; 7,548,112; 7,592,211; 7,615,774; 7,709,269; 7,709,859; and 10,971,612, the disclosures of which are incorporated by reference herein in their entireties. Additionally, strain balancing transition layer(s) may also and/or alternatively be provided as described, for example, in U.S. Pat. No. 7,030,428, the disclosure of which is incorporated by reference herein.

The unit cell transistor 102 of the HEMT device 100 includes a source finger 108 on the semiconductor transistor structure 12. The unit cell transistor 102 of the HEMT device 100 also includes a drain finger 106 on the semiconductor transistor structure 12. The source finger 108 and the drain finger 106 are laterally spaced apart from each other. The source finger 108 and the drain finger 106 comprise an ohmic metal, which forms an ohmic contact to a Group III nitride-based semiconductor material. Suitable metals include refractory metals, such as titanium (Ti), tungsten (W), titanium tungsten (TiW), silicon (Si), titanium tungsten nitride (TiWN), tungsten silicide (WSi), rhenium (Re), niobium (Nb), nickel (Ni), gold (Au), aluminum (Al), tantalum (Ta), molybdenum (Mo), NiSiₓ, titanium silicide (TiSi), titanium nitride (TiN), tungsten silicon nitride (WSiN), platinum (Pt) and the like. In some aspects, the source finger 108 and/or the drain finger 106 may include a plurality of layers to form an ohmic contact as described, for example, in U.S. Pat. Nos. 8,563,372 and 9,214,352, the disclosures of which are incorporated by reference herein in their entireties.

The unit cell transistor 102 of the HEMT device 100 includes a gate finger 104 on the semiconductor transistor structure 12. The gate finger 104 has a gate length L_{G}. The gate length L_{G} is the length of the gate contact 104 along the portion of the gate contact 104 that is on the semiconductor transistor structure 12 (e.g., the length of the lowermost portion of the gate finger 104 in contact with the semiconductor transistor structure 12). In some aspects, the gate length L_{G} may be about 200 nm or less, such as about 100 nm or less, such as in a range of about 60 nm to about 100 nm, such as in a range of about 70 nm to about 90 nm. A distance Lgd between the gate finger 104 and the drain finger 106 may be, for instance, in a range of 1.8 μm to about 2.2 μm, such as about 1.98 μm. A distance Lgs between the gate finger 104 and the source finger 108 may be, for instance, in a range of about 0.4 μm to about 0.8 μm, such as about 0.6 μm.

The material of the gate finger 104 may be chosen based on the composition of the barrier layer 18, and may, in some aspects, be a Schottky contact. Materials capable of making a Schottky contact to a Group III nitride-based semiconductor material may be used, such as, for example, nickel (Ni), platinum (Pt), nickel silicide (NiSiₓ), copper (Cu), palladium (Pd), chromium (Cr), tungsten (W) and/or tungsten silicon nitride (WSiN).

In some aspects of the present disclosure, such as that depicted in FIG. 6, the gate finger 104 is a T-shaped gate and/or a gamma gate, the formation of which is discussed by way of example in U.S. Pat. Nos. 8,049,252; 7,045,404; and 8,120,064, the disclosures of which are incorporated by reference herein in their entireties. The gate finger 104 may have an overhang toward the drain finger 106. The length Γ_{D} of the overhang toward the drain finger 106 may be in a range of about 0.15 μm to about 0.25 μm, such as about 0.2 μm. The gate finger 104 may have an overhang toward the source finger 108. The length Γ_{S} of the overhang toward the source finger 108 may be in a range of about 0.15 μm to about 0.25 μm, such as about 0.2 μm.

As FIG. 6 shows, the source finger 108 is formed over, and electrically connected to, a plated via 114 that extends from a lower surface 116B of the substrate 116, through the substrate 116 and semiconductor transistor structure 12 to the upper surface of the semiconductor transistor structure 12. A back metal layer 30 is formed on the lower surface 116B of the substrate 116 and on side walls of the via 114. The back metal layer 30 is conductively coupled to the source finger 108. The back metal layer 30 may couple to RF signal ground.

In some aspects of the present disclosure, the via 114 has an oval or circular cross-section when viewed in a plan view (e.g., FIG. 1). However, the present disclosure is not limited thereto. In some aspects of the present disclosure, a cross-section of the via 114 may be a polygon or other shape, as will be understood by one of ordinary skill in the art using the disclosures provided herein. In some aspects of the present disclosure, dimensions of the via 114 (e.g., a length and/or a width) may be such that the largest cross-sectional area of the via 114 is about 1000 μm² or less. The cross-sectional area may be taken in a direction that is parallel to the lower surface 14B of the substrate 116 (e.g., the X-Y plane of FIG. 1). In some aspects of the present disclosure, the largest cross-sectional area of the via 114 may be that portion of the via 114 that is adjacent the lower surface 116B of the substrate 116 (e.g., the opening of the via 114). For example, in some aspects of the present disclosure, a greatest width (e.g., in the X direction in FIG. 6) may be about 16 μm and a greatest length (e.g., in the Y direction in FIG. 6) may be about 40 μm, though the present disclosure is not limited thereto. In some aspects of the present disclosure, sidewalls of the via 114 may be inclined and/or slanted with respect to the lower surface 116B of the substrate 116. In some aspects of the present disclosure, the sidewalls of the via 114 may be approximately perpendicular to the lower surface 116B of the substrate 116.

As FIG. 6 shows, a dielectric layer 124 is deposited over at least part of the source finger 108. A metal layer 126 is deposited over the dielectric layer 124. The source finger 108, dielectric layer 124, and metal layer 126 form a MIMcap 122, which is electrically connected to RF signal ground via the source finger's 108 connection to the via(s) 114. A bond wire 120 is attached to the upper surface of the metal layer 126 of the MIMcap 122. The bond wire 120 connects to one of a gate bond pad 110 and a drain bond pad 112. The gate and drain bond pads 110, 112 are not shown in the section view of FIG. 6, as they are out of the plane of the drawing figure (i.e., in front of or behind it). The MIMcap 122 and bond wire 120 form a harmonic termination circuit 118 comprising a shunt series resonant LC circuit connected between either the gate bond pad 110 or the drain bond pad 112 and RF signal ground. The series resonant LC circuit may be tuned to present a high impedance at a fundamental frequency of the RF amplifier 100, and a low impedance at a selected harmonic of the fundamental frequency.

The unit cell transistor 102 of the HEMT device 100 includes a first dielectric layer 32 on the semiconductor transistor structure 12. The first dielectric layer 32 directly contacts the upper surface of the semiconductor transistor structure 12. At least a portion of the first dielectric layer 32 is between the semiconductor transistor structure 12 and at least a portion of the gate finger 104. For instance, at least a portion of the first dielectric layer 32 may be between the semiconductor transistor structure 12 and the overhang of the gate finger 104. In some aspects of the present disclosure, the thickness of the first dielectric layer 32 may be about 1450 Angstroms or less, such as in a range of about 800 Angstroms to about 1450 Angstroms, such as about 1200 Angstroms. In this way, the overhang of the T-shaped or Gamma-shaped gate finger 104 is separated from the semiconductor transistor structure 12 by the thickness of the first dielectric layer 32. The first dielectric layer 32 may be a SiN layer. Other suitable dielectric materials may be used without deviating from the scope of the present disclosure. For instance, the first dielectric layer 32 may be SiO₂, Si, Ge, MgOx, MgNx, ZnO, SiNx, SiOx, alloys or layer sequences thereof, or epitaxial materials.

In some aspects of the present disclosure, a second dielectric layer (not shown) may be deposited on the first dielectric layer 32. The second dielectric layer may be the same dielectric material or a different dielectric material relative to the first dielectric layer 32. For instance, the second dielectric layer may be a SiN layer. Other suitable dielectric materials may be used without deviating from the scope of the present disclosure. For instance, the second dielectric layer may be SiO₂, Si, Ge, MgOx, MgNx, ZnO, SiNx, SiOx, alloys or layer sequences thereof, or epitaxial materials. In some embodiments, the thickness of the second dielectric layer may be about 2800 Angstroms or less, such as in a range of about 1500 Angstroms to about 2800 Angstroms, such as about 2100 Angstroms.

In some embodiments, the thickness of the first and second dielectric layers may be about 3600 Angstroms or less, such as in a range of about 3000 Angstroms to about 3600 Angstroms, such as about 3300 Angstroms.

One or more field plates (not shown) may be formed on the second dielectric layer. At least a portion of the field plate overlaps the gate finger 104. At least a portion of the field plate is formed on a portion of the second dielectric layer. In some aspects of the present disclosure, the field plate is conductively coupled to the gate finger 104. The field plate may reduce the peak electric field in the unit cell transistor 102 of the HEMT device 100, which results in increased breakdown voltage and reduced charge trapping. The reduction of the electric field may also yield other benefits such as reduced leakage currents and enhanced reliability. Field plates and techniques for forming field plates are discussed, by way of example, in U.S. Pat. Nos. 7,550,783 and 8,120,064, the disclosures of which are incorporated by reference herein in their entireties. In embodiments in which a field plate or other structure is formed, the source fingers 108, gate bond pad 110, and drain bond pad 112 are the highest, or uppermost, structures in the semiconductor device. In some designs, the gate bond pad 110, and drain bond pad 112 may connect to gate fingers 104 and drain fingers 106 through vias, as well known in the art, and not further elaborated herein.

A HEMT transistor cell 102 may be formed by the active region between the source finger 108 and the drain finger 106 under the control of the gate finger 104 between the source finger 108 and the drain finger 106. FIG. 6 depicts a cross-sectional view of one unit or cell 102 of an HEMT device 100 for purposes of illustration. As shown in FIG. 1, the HEMT device unit or cell 102 may be formed adjacent to additional HEMT device cells and may share, for instance, a source finger 108 with adjacent HEMT device cells 102. The HEMT device 100 may be formed, at least in part, via wafer-level processing, and the wafer may then be diced to provide a plurality of individual HEMT devices 100.

In some aspects of the present disclosure, the semiconductor transistor structure 12 may include implanted regions under the source finger 108 and drain finger 106 (not shown). The implanted regions include a distribution of implanted dopants extending into the channel layer 16. The implanted dopants may provide, for instance, for N-type doping of the semiconductor transistor structure 12. The implanted dopants may be, for instance, silicon or germanium dopants. The implanted region may have a distribution of implanted dopants that extends to a depth from a surface (e.g., a top surface) of the semiconductor transistor structure 12. The depth may be about 200 Angstroms or greater, such as about 250 Angstroms or greater, such as in a range of about 200 Angstroms to about 300 Angstroms. For instance, in some aspects of the present disclosure, the implanted region 302 can extend to a depth of about 200 Angstroms to about 300 Angstroms beneath a surface of the Group III-nitride semiconductor structure. In particular, the implanted region can extend completely through the barrier layer 18 and into the channel layer 16. The distribution of implanted dopants may extend through other layers, if present, such as a cap layer.

The implanted regions may have a peak dopant concentration. In some aspects of the present disclosure, a peak dopant concentration of the distribution of implanted dopants in the implanted regions is in the channel layer 16. For instance, the implanted regions may be doped such that the distribution of implanted dopants is greater at a portion of the implanted regions at a depth of the channel layer 16 than at a portion of the implanted regions at a depth of the barrier layer 18 (and/or another layer). In some examples, the distribution of implanted dopants may provide a substantially uniform concentration of implanted dopants throughout the implanted regions of the semiconductor transistor structure 12. In some aspects of the present disclosure, a peak dopant concentration of the distribution of implanted dopants can be about 1×10¹⁸ dopants/cm³.

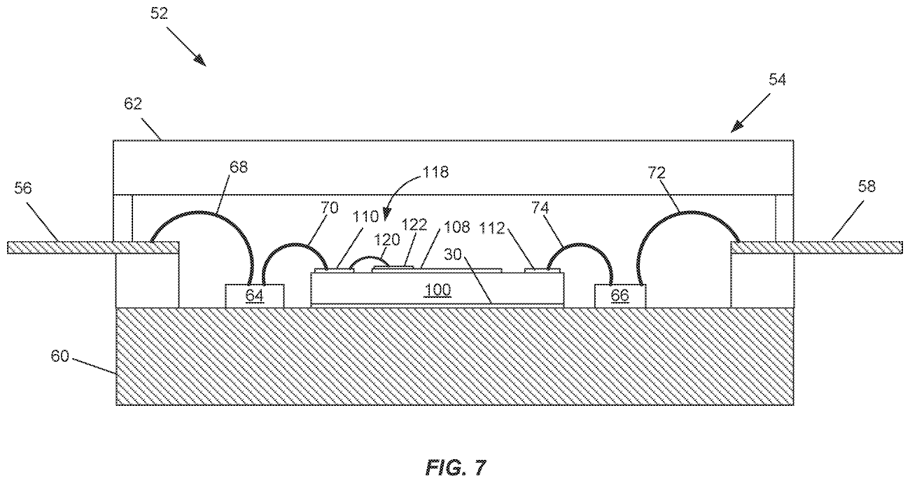

The RF amplifier with integrated harmonic termination circuit 118 may be packaged in a variety of ways. FIG. 7 shows a Group III nitride-based RF amplifier 52, which includes a unit cell configuration of parallel HEMTs 100 mounted within an open cavity package 54. The package 54 includes a gate lead 56, a drain lead 58, a metal flange 60 and a ceramic sidewall and lid 62. The HEMT 100 is mounted on the upper surface of the metal flange 60 in a cavity formed by the metal flange 60 and the ceramic sidewall and lid 62.

Input matching circuits 64 and/or output matching circuits 66 may also be mounted within the housing 62. The matching circuits 64, 66 may be impedance matching circuits that match the impedance of the fundamental component of RF signals input to or output from the RF transistor amplifier 52 to the impedance at the input or output of the HEMT 100, respectively. As schematically shown in FIG. 7, the input and output matching circuits 64, 66 may be mounted on the metal flange 60. The gate lead 56 may be connected to the input matching circuit 64 by one or more first bond wires 68, and the input matching circuit 64 may be connected to the gate bond pad 110 of HEMT 100 by one or more second bond wires 70. Similarly, the drain lead 58 may be connected to the output matching circuit 66 by one or more fourth bond wires 72, and the output matching circuit 66 may be connected to the drain bond pad 112 of HEMT 100 by one or more third bond wires 74.

The source finger 108 of the HEMT 100 may connect to the metal layer 30 on the lower side of the substrate 14, which may directly contact the metal flange 60. As shown, the harmonic termination circuit 118 described herein comprises a MIMcap 122 formed on a source finger 108, and a bond wire 120 connecting the MIMcap 122 to, in this case, the gate bond pad 110. The metal flange 60 may provide the electrical connection to the source finger 108 and may also serve as a heat dissipation structure. The first through fourth bond wires 68-74 may form part of the input and/or output matching circuits. The housing 62 may comprise a ceramic housing, and the gate lead 56 and the drain lead 58 may extend through the housing 52. The housing 52 may comprise multiple pieces, such as a frame that forms the lower portion of the sidewalls and supports the gate and drain leads 56, 58, and a lid that is placed on top of the frame. The interior of the device may comprise an air-filled cavity.

The metal flange 60 may act as a heat sink that dissipates heat that is generated in the HEMT 100. The heat is primarily generated in the upper portion of the HEMT 100 where relatively high current densities are generated in, for example, the channel regions of the unit cell transistors 102. This heat may be transferred though both the source vias 114 and the substrate 116 to the metal flange 60.

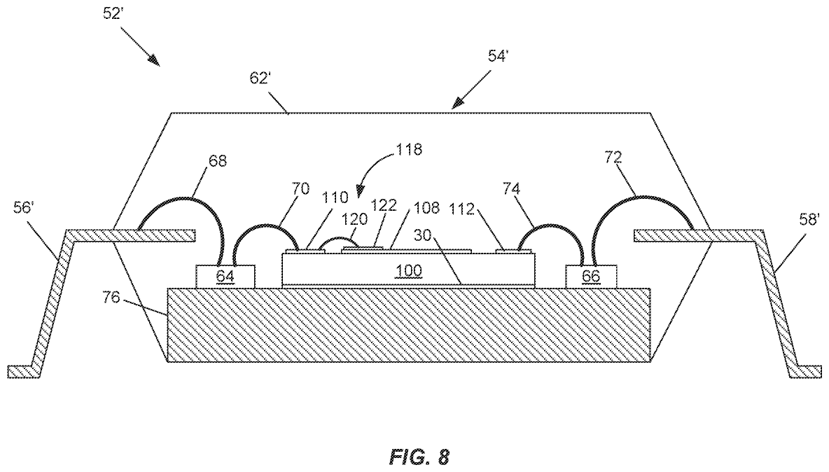

FIG. 8 is a schematic side view of a conventional packaged Group III nitride-based RF transistor amplifier 52′ that is similar to the RF transistor amplifier 52 discussed above with reference to FIG. 7. RF transistor amplifier 52′ differs from RF transistor amplifier 52 in that it includes a different package 54′. The package 54′ includes a metal submount 76 (which acts as a metal heat sink and can be implemented as a metal slug), as well as gate and drain leads 56′, 58′. In some embodiments, a metal lead frame may be formed that is then processed to provide the metal submount 76 and/or the gate and drain leads 56′, 58′. RF transistor amplifier 52′ also includes a plastic overmold 62′ that at least partially surrounds the HEMT 100, the leads 56′, 58′ and the metal submount 76. The plastic overmold 62′ replaces the ceramic sidewalls and lid 62 included in RF transistor amplifier 52.

Depending on the embodiment, the packaged transistor amplifier 52′ can include, for example, a monolithic microwave integrated circuit (MMIC) as the HEMT 100 in which case the HEMT 100 incorporates multiple discrete devices. When the HEMT 100 is a MMIC implementation, the input matching circuits 64 and/or the output matching circuits 66 may be omitted (since they may instead be implemented within the HEMT 100) and the bond wires 68 and/or 72 may extend directly from the gate and drain leads 56′, 58′ to the gate bond pad 50 and drain metal contact 48. In some embodiments, the packaged RF transistor amplifier 52 can include multiple RF transistor amplifier die that are connected in series to form a multiple stage RF transistor amplifier and/or may include multiple transistor die that are disposed in multiple paths (e.g., in parallel) to form an RF transistor amplifier with multiple RF transistor amplifier die and multiple paths, such as in a Doherty amplifier configuration.

In other cases, Group III nitride-based RF amplifiers may be implemented as monolithic microwave integrated circuit (“MMIC”) devices in which one or more RF amplifier die(s) are implemented together with their associated impedance matching and harmonic termination circuits in a single, integrated circuit die. Examples of such Group III nitride-based RF amplifiers are disclosed, for example, in U.S. Pat. No. 9,947,616, the entire content of which is incorporated herein by reference.

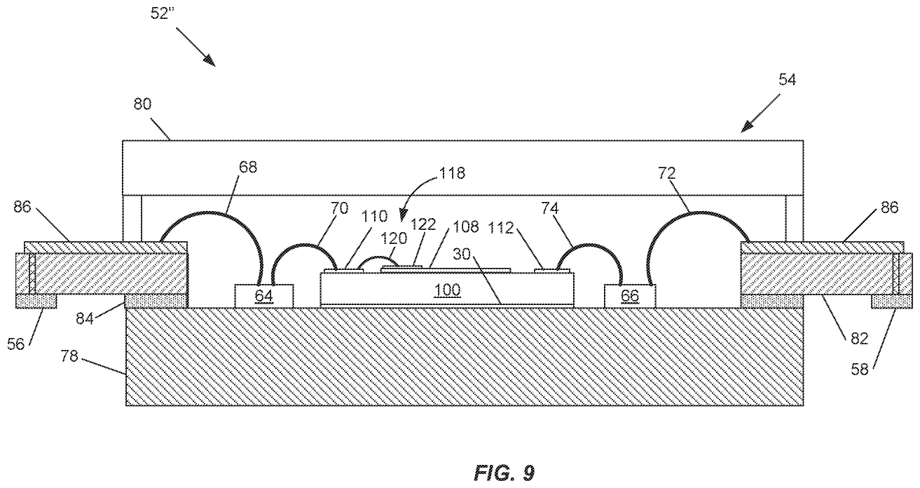

FIG. 9 is a cross-sectional view illustrating an example of a thermally enhanced integrated circuit device package, more specifically a T3PAC package. The T3PAC package 52″ of FIG. 9 can be a ceramic-based package that includes a base 78 and an upper housing with a lid member 80 and sidewall members 82. The lid member 80 and sidewalls 82 similarly define an open cavity surrounding the HEMT 100 on the conductive base or flange 78, which likewise provides both an attachment surface and thermal conductivity (e.g., a heat sink) for dissipating or otherwise transmitting heat outside of the package 600″.

The flange 78 can be an electrically conductive material, for example, a copper layer/laminate or an alloy or metal-matrix composite thereof. In some embodiments, the flange 78 may include a copper-molybdenum (CuMo) layer, CPC (Cu/MoCu/Cu), or other copper alloys, such copper-tungsten CuW, and/or other laminate/multi-layer structures. In the example of FIG. 9, the flange 78 is illustrated as a copper-molybdenum (RCM60)-based structure to which the sidewalls 82 and/or lid member 80 are attached, e.g., by a conductive glue 1208.

The flange 78 also provides the source lead for the package 52″. The gate lead 56 and drain lead 58 are provided by respective conductive wiring structure 86 which is attached to the flange 78 and supported by the sidewall members 82.

Aspects of the present invention present numerous advantages over the prior art. Component count is reduced, compared to solutions that provide harmonic termination circuitry off-chip. Where harmonic termination circuitry is integrated, the capacitor structure and inductor traces or transmission line must be formed separately from the RF amplifier, which increases the size, and hence cost, of the die. By integrating the inventive harmonic termination circuit 188 into the RF amplifier 100, both component count and die area are reduced, both of which save cost. The MIMcaps 122 are inherently high Q (low loss), leading to improved harmonic termination and better efficiency compared to off-chip capacitors. The bond wires are inherently high Q (low loss), leading to improved harmonic termination and better efficiency compared to on-chip spiral inductors or transmission lines. The harmonic termination circuit 188 is easily tuned to modify the harmonic termination frequency, by adjusting the length of the bond wires. This eliminates the need to re-design the circuit and re-fabricate the die in case the harmonic design was slightly off, and allows for broader reuse of the die, such as for applications operating a different fundamental frequency. The technique can be applied to the input, the output, or both. Multiple harmonics can be terminated at either or both of the input and output.

The present invention may, of course, be carried out in other ways than those specifically set forth herein without departing from essential characteristics of the invention. The present embodiments are to be considered in all respects as illustrative and not restrictive, and all changes coming within the meaning and equivalency range of the appended claims are intended to be embraced therein. Although steps of various processes or methods described herein may be shown and described as being in a sequence or temporal order, the steps of any such processes or methods are not limited to being carried out in any particular sequence or order, absent an indication otherwise. Indeed, the steps in such processes or methods generally may be carried out in various different sequences and orders while still falling within the scope of the present invention.

What is claimed is:

1. A semiconductor transistor configured to amplify a Radio Frequency (RF) signal at a fundamental frequency, comprising:
a substrate having upper and lower surfaces;
a unit cell semiconductor transistor structure formed on the upper surface of the substrate;
source and drain fingers formed directly on, and electrically connected to, the semiconductor transistor structure;
gate fingers formed over the semiconductor transistor structure in active areas between the source and drain fingers;
gate and drain bond pads connected to respective gate and drain fingers;
wherein the source fingers are electrically connected to RF signal ground; and
a series resonant circuit connected between one of the gate and drain bond pads and a source finger, the series resonant circuit comprising
a Metal-Insulator-Metal (MIM) capacitor formed on the source finger; and
an inductance implemented as a bond wire connected between the gate or drain bond pad and the MIM capacitor.

2. The transistor of claim 1 wherein the series resonant circuit is configured to present a low impedance path to RF signal ground at a selected harmonic of the fundamental frequency.

3. The transistor of claim 2 wherein the series resonant circuit is configured to be tuned by adjusting a length of the bond wire.

4. The transistor of claim 3 wherein the length of the bond wire is adjusted by varying its height.

5. The transistor of claim 3 wherein the length of the bond wire is adjusted after fabrication of the semiconductor transistor is otherwise complete.

6. The transistor of claim 1 further comprising:
a via through the substrate and electrically connected to a conductive layer formed on the lower surface of the substrate;
wherein the conductive layer is electrically connected to RF signal ground; and
wherein the source terminal is formed over, and electrically connected to, the via.

7. The transistor of claim 1 wherein the MIM capacitor comprises:
the source terminal;
an insulator deposited over at least part of the source terminal; and
a metal layer deposited over the insulator.

8. The transistor of claim 7 wherein the bond wire is connected to the metal layer.

9. A method of manufacturing a semiconductor transistor configured to amplify a Radio Frequency (RF) signal at a fundamental frequency, comprising:
providing a substrate having upper and lower surfaces;
forming a unit cell semiconductor transistor structure on the upper surface of the substrate;
forming source and drain fingers directly on, and electrically connected to, the semiconductor transistor structure;
forming gate fingers over the semiconductor transistor structure in active areas between the source and drain fingers;
forming gate and drain bond pads connected to respective gate and drain fingers;
electrically connecting the source fingers to RF signal ground; and
forming a series resonant circuit connected between one of the gate and drain bond pads and a source finger, comprising
forming a Metal-Insulator-Metal (MIM) capacitor on the source finger; and
connecting a bond wire between the gate or drain bond pad and the MIM capacitor.

10. The method of claim 9 wherein the series resonant circuit is configured to present a low impedance path to RF signal ground at a selected harmonic of the fundamental frequency.

11. The method of claim 10 further comprising tuning the series resonant circuit by adjusting a length of the bond wire.

12. The method of claim 11 wherein adjusting a length of the bond wire comprises varying its height.

13. The method of claim 11 wherein tuning the series resonant circuit occurs after fabrication of the semiconductor transistor is otherwise complete.

14. The method of claim 9 further comprising:
a via through the substrate and electrically connected to a conductive layer formed on the lower surface of the substrate;
wherein the conductive layer is electrically connected to RF signal ground; and
wherein the source terminal is formed over, and electrically connected to, the via.

15. The method of claim 9 wherein the MIM capacitor comprises:
the source terminal;
an insulator deposited over at least part of the source terminal; and
a metal layer deposited over the insulator.

16. The method of claim 15 wherein the bond wire is connected to the metal layer.
